(19) United States
(12) Patent Application Publication
(10) Pub. No.: US 2006/0186461 A1
(43) Pub. Date: Aug. 24, 2006

(54) Semiconductor device and method of manufacturing the same

(76) Inventor: Wakako Takeuchi, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/356,072

(22) Filed: Feb. 17, 2006

(30) Foreign Application Priority Data
Feb. 18, 2005 (JP) 2005-042318

(51) Int. Cl. H01L 29/788

(52) U.S. Cl. 257/315

(57) ABSTRACT

According to an aspect of the invention, there is provided a semiconductor device comprising a semiconductor substrate, a gate insulating film formed on the semiconductor substrate, a gate electrode formed on the gate insulating film, and a diffusion layer formed in the semiconductor substrate, a predetermined portion of the gate electrode in the vicinity of the diffusion layer being provided with an impurity area whose conductive type is different from that of another portion of the gate electrode or an impurity area whose conductive type is the same as that of the other portion and whose concentration is lower than that of the other portion.

### CROSS-REFERENCE TO RELATED APPLICATIONS

This application is based upon and claims the benefit of priority from prior Japanese Patent Application No. 2005-042318, filed Feb. 18, 2005, the entire contents of which are incorporated herein by reference.

### BACKGROUND OF THE INVENTION

1. Field of the Invention

The present invention relates to a semiconductor device such as a NAND type EEPROM, and a method of manufacturing the same.

2. Description of the Related Art

A NAND type flash memory has a cell array structure provided with a plurality of cell transistors which are constituted of n-channel MOS-FETs having floating gates and control gates and which are connected in series. In such cell array structure, there is a problem that an electron comes off from a cell written with “0” by a voltage applied to a gate edge portion during writing of a cell disposed adjacent to the written cell, and “0”→“1” sometimes results.

It is to be noted that in Jpn. Pat. Appln. KOKAI Publication No. 9-17891, in a flash EEPROM, each of curvature radiuses of edges of opposite sides of a floating gate is set to 50 nm or more, the opposite sides including a source area side and a drain area side brought into contact with a tunnel insulating film. Accordingly, occurrence of excessive erase is prevented.

### BRIEF SUMMARY OF THE INVENTION

According to an aspect of the invention, there is provided a semiconductor device comprising: a semiconductor substrate; a gate insulating film formed on the semiconductor substrate; a gate electrode formed on the gate insulating film; and a diffusion layer formed in the semiconductor substrate, a predetermined portion of the gate electrode in the vicinity of the diffusion layer being provided with an impurity area whose conductive type is different from that of another portion of the gate electrode or an impurity area whose conductive type is the same as that of the other portion and whose concentration is lower than that of the other portion.

According to another aspect of the invention, there is provided a semiconductor device comprising: a semiconductor substrate; a first gate insulating film formed on the semiconductor substrate; a first gate electrode formed on the first gate insulating film; a second gate insulating film formed on the first gate electrode; a second gate electrode formed on the second gate insulating film; and a diffusion layer formed in the semiconductor substrate, a predetermined portion of the first gate electrode in the vicinity of the diffusion layer being provided with an impurity area whose conductive type is different from that of another portion of the first gate electrode or an impurity area whose conductive type is the same as that of the other portion and whose concentration is lower than that of the other portion.

According to another aspect of the invention, there is provided a method of manufacturing a semiconductor device, comprising: forming a gate insulating film on a semiconductor substrate; forming a gate electrode on the gate insulating film; implanting impurities in a predetermined portion of the gate electrode; and forming a diffusion layer in the semiconductor substrate, a predetermined portion of the gate electrode in the vicinity of the diffusion layer being provided with an impurity area whose conductive type is different from that of another portion of the gate electrode or an impurity area whose conductive type is the same as that of the other portion and whose concentration is lower than that of the other portion.

According to another aspect of the invention, there is provided a method of manufacturing a semiconductor device, comprising: forming a first gate insulating film on a semiconductor substrate; forming a first gate electrode on the first gate insulating film; forming a second gate insulating film on the first gate electrode; forming a second gate electrode on the second gate insulating film; implanting impurities in a predetermined portion of the first gate electrode; and forming a diffusion layer in the semiconductor substrate, a predetermined portion of the first gate electrode in the vicinity of the diffusion layer being provided with an impurity area whose conductive type is different from that of another portion of the first gate electrode or an impurity area whose conductive type is the same as that of the other portion and whose concentration is lower than that of the other portion.

### BRIEF DESCRIPTION OF THE SEVERAL VIEWS OF THE DRAWING

FIGS. 1A and 1B are diagrams showing a cell array structure of a NAND type flash memory in an embodiment of the present invention;

FIG. 2 is a sectional view of a NAND type flash memory in a first embodiment of the present invention;

FIG. 3 is a sectional view of the NAND type flash memory in the first embodiment of the present invention;

FIG. 4 is a sectional view of the NAND type flash memory in the first embodiment of the present invention;

FIG. 5 is a sectional view of the NAND type flash memory in the first embodiment of the present invention;

FIG. 6 is a sectional view of the NAND type flash memory in the first embodiment of the present invention;

FIG. 7 is a sectional view of the NAND type flash memory in the first embodiment of the present invention;

FIG. 8 is a sectional view of the NAND type flash memory in the first embodiment of the present invention;

FIG. 9 is a sectional view of the NAND type flash memory in the first embodiment of the present invention;

FIGS. 10A and 10B show diagrams showing sectional structures of the memory transistors and band diagrams in the first embodiment of the present invention;

FIG. 11 is a diagram showing a cell array structure in the first embodiment of the present invention;

FIG. 12 is a diagram showing a state of the memory transistor in the first embodiment of the present invention;

FIG. 13 is a diagram showing a state of the memory transistor in the first embodiment of the present invention;

FIG. 14 is a diagram showing a state of the memory transistor in the first embodiment of the present invention;

FIG. 15 is a diagram showing a state of the memory transistor in the first embodiment of the present invention;

FIG. 16 is a diagram showing a state of the memory transistor in the first embodiment of the present invention;

FIG. 17 is a sectional view of a NAND type flash memory in a second embodiment of the present invention;

FIG. 18 is a sectional view of the NAND type flash memory in the second embodiment of the present invention;

FIG. 19 is a sectional view of the NAND type flash memory in the second embodiment of the present invention;

FIGS. 20A and 20B show diagrams showing sectional structures of the memory transistors and band diagrams in the second embodiment of the present invention;

FIG. 21 shows a diagram showing a sectional structure of a MOSFET that is a modification of the second embodiment.

FIG. 22 is a sectional view of a NAND type flash memory in a third embodiment of the present invention;

FIG. 23 is a sectional view of the NAND type flash memory in the third embodiment of the present invention;

FIG. 24 is a sectional view of the NAND type flash memory in the third embodiment of the present invention;

FIG. 25 is a sectional view of the NAND type flash memory in the third embodiment of the present invention;

FIGS. 26A and 26B show diagrams showing sectional structures of the memory transistors and band diagrams in the third embodiment of the present invention;

FIG. 27 is a diagram showing a state of a memory transistor in the third embodiment of the present invention;

FIG. 28 is a diagram showing a state of the memory transistor in the third embodiment of the present invention;

FIG. 29 is a diagram showing a state of the memory transistor in the third embodiment of the present invention;

FIG. 30 is a diagram showing a state of the memory transistor in the third embodiment of the present invention;

FIG. 31 is a diagram showing a state of the memory transistor in the third embodiment of the present invention;

FIG. 32 is a sectional view of a NAND type flash memory in a fourth embodiment of the present invention;

FIG. 33 is a sectional view of the NAND type flash memory in the fourth embodiment of the present invention;

FIG. 34 is a sectional view of the NAND type flash memory in the fourth embodiment of the present invention;

FIG. 35 is a sectional view of the NAND type flash memory in the fourth embodiment of the present invention;

FIG. 36 is a sectional view of the NAND type flash memory in the fourth embodiment of the present invention;

FIG. 37 is a sectional view of the NAND type flash memory in the fourth embodiment of the present invention;

FIG. 38 is a sectional view of the NAND type flash memory in the fourth embodiment of the present invention;

FIG. 39 is a sectional view of the NAND type flash memory in the fourth embodiment of the present invention;

FIGS. 40A and 40B show diagrams showing sectional structures of the memory transistors and band diagrams in the fourth embodiment of the present invention;

FIG. 41 is a diagram showing a cell array structure in the fourth embodiment of the present invention;

FIG. 42 is a diagram showing a state of the memory transistor in the fourth embodiment of the present invention;

FIG. 43 is a diagram showing a state of the memory transistor in the fourth embodiment of the present invention;

FIG. 44 is a diagram showing a state of the memory transistor in the fourth embodiment of the present invention;

FIG. 45 is a diagram showing a state of the memory transistor in the fourth embodiment of the present invention; and

FIG. 46 is a diagram showing a state of the memory transistor in the fourth embodiment of the present invention.

### DETAILED DESCRIPTION OF THE INVENTION

Embodiments of the present invention will be described hereinafter with reference to the drawings.

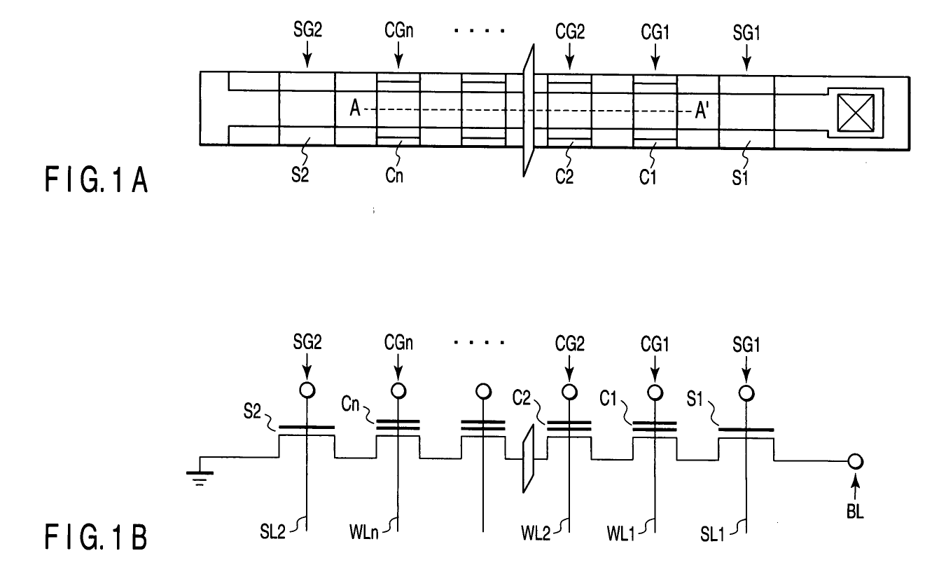

FIGS. 1A and 1B are diagrams showing a cell array structure of a NAND type flash memory (NAND type EEPROM (electrically erasable, writable semiconductor memory) which is a semiconductor device in a first embodiment of the present invention, FIG. 1A is a plan view, and FIG. 1B is an equivalent circuit diagram of a section. In FIGS. 1A and 1B, a plurality of cell transistors C1 to Cn (n=2, 3 . . . ) are connected in series which are constituted of n-channel MOS-FETs having floating gates and control gates. A drain on one end of this array is connected to a bit line BL via an NMOS transistor S1 for selection, and a source on the other end is connected to a source line via an NMOS transistor S2 for selection.

The above-described transistors are formed on the same well substrate. Control electrodes CG1 to CGn of the cell transistors C1 to Cn are connected to word lines WL1 to WLn continuously arranged in a row direction. A control electrode SG1 of the selection transistor S1 is connected to a selection line SL1, and a control electrode SG2 of the selection transistor S2 is connected to a selection line SL2. One end of each of the word lines WL1 to WLn has a connection pad to a peripheral circuit via an Al wire, and is formed on a device separating film.

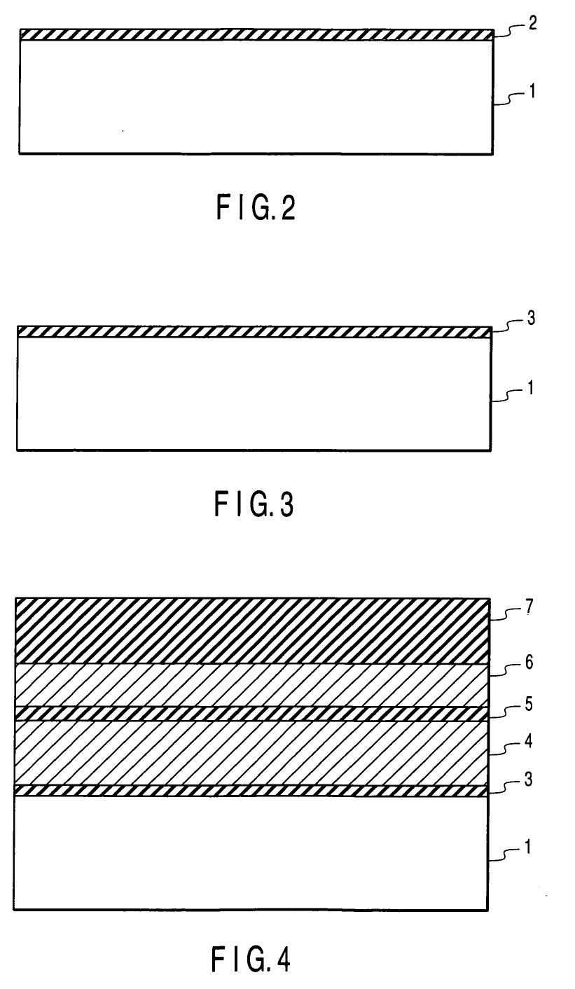

FIGS. 2 to 9 are sectional views cut along the line A-A′ of FIG. 1A. There will be described steps of manufacturing a cell array of a NAND type flash memory with reference to FIGS. 2 to 9.

First, as shown in FIG. 2, a silicon oxide film 2 is formed on a silicon substrate (semiconductor substrate) 1 by use of a thermal oxidation method. This silicon oxide film 2 is nitrided by use of an NH₃ gas, and oxidized to thereby form an oxynitride film 3 as shown in FIG. 3. This oxynitride film 3 works as a first gate insulating film, and is generally referred to as a tunnel insulating film.

Furthermore, as shown in FIG. 4, there is formed a silicon film 4 to which boron (B) has been added as impurities on the oxynitride film 3 by use of a CVD method. This silicon film 4 forms a first gate electrode. In general, this silicon film 4 is referred to as a floating gate. Subsequently, a second gate insulating film 5 having a film thickness of 120 nm is formed on this floating gate 4 by use of an LPCVD method. Next, there is formed a silicon film 6 to which boron (B) has been added as impurities on the second gate insulating film 5 by use of the LPCVD method. This silicon film 6 forms a second gate electrode, and is generally referred to as a control gate. Subsequently, a silicon nitride film 7 is formed on this control gate 6 by use of the LPCVD method.

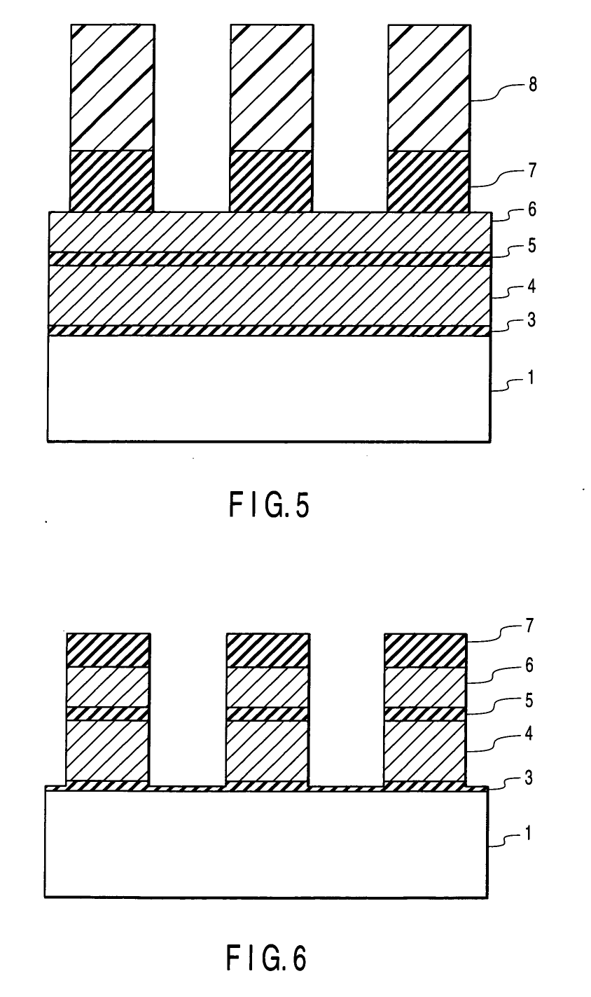

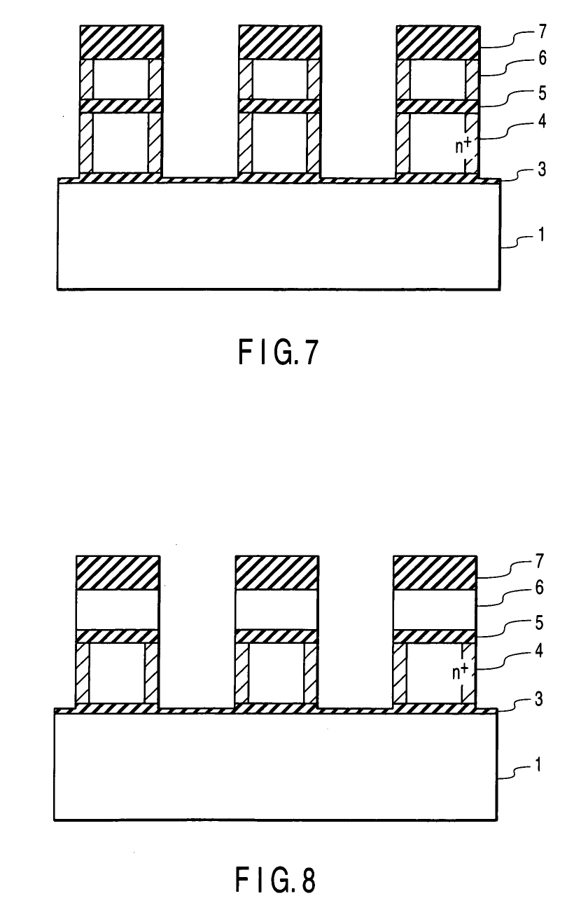

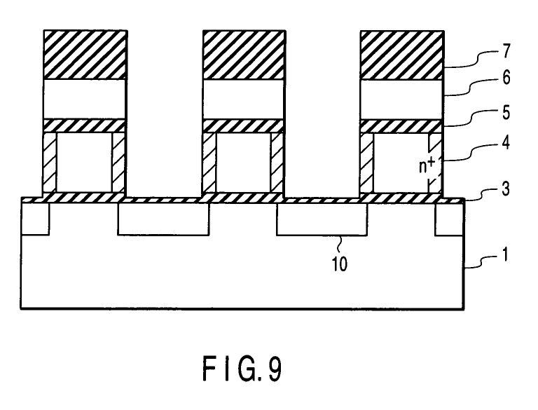

Furthermore, as shown in FIG. 5, the silicon nitride film 7 is coated with a photo resist 8. A desired pattern is worked using a lithography method, and subsequently the photo resist 8 is removed. As shown in FIG. 6, the control gate 6, the second gate insulating film 5, and the floating gate 4 are successively etched in a vertical direction by use of the nitride film 7 as a mask. Furthermore, as shown in FIG. 7, phosphor (P) is ion-implanted obliquely from above into an edge portion of the floating gate 4. Accordingly, p+poly, for example, a side wall of a p-type polysilicon having an impurity concentration of about 2×10²⁰ atom/cm³ forms the floating gate 4 which is an n-type impurity area (n+) having an impurity concentration of, for example, about 2×10²⁰ atom/cm³. Next, as shown in FIG. 8, boron is ion-implanted with an angle obliquely from above, and the control gate 6 is formed into p+poly. Furthermore, as shown in FIG. 9, to form a source and a drain, ions are implanted in the silicon substrate 1, the substrate is activated by thermal annealing to form a diffusion layer 10, and a memory transistor is formed.

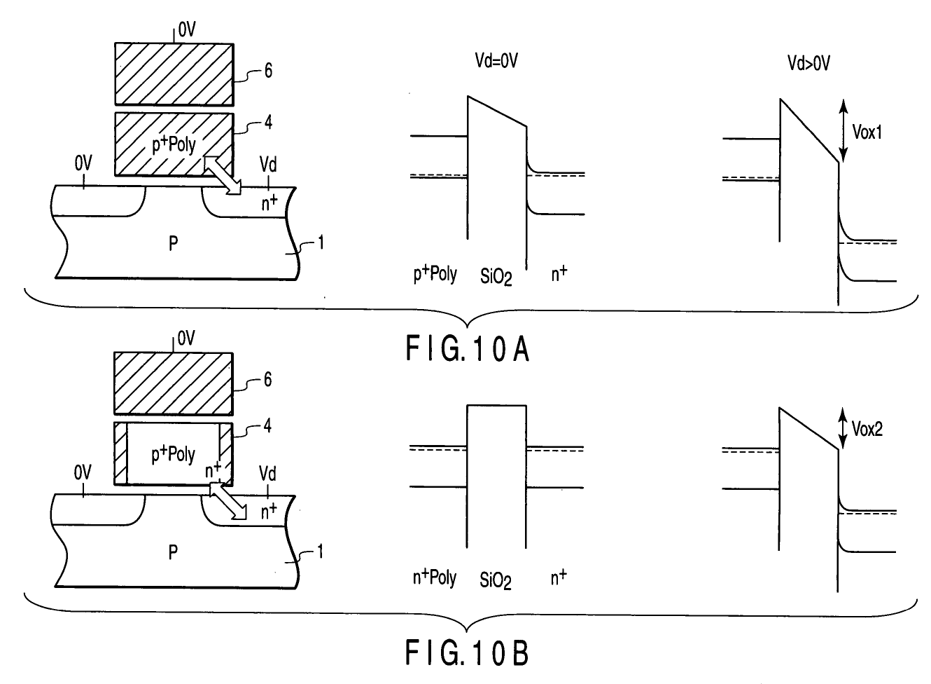

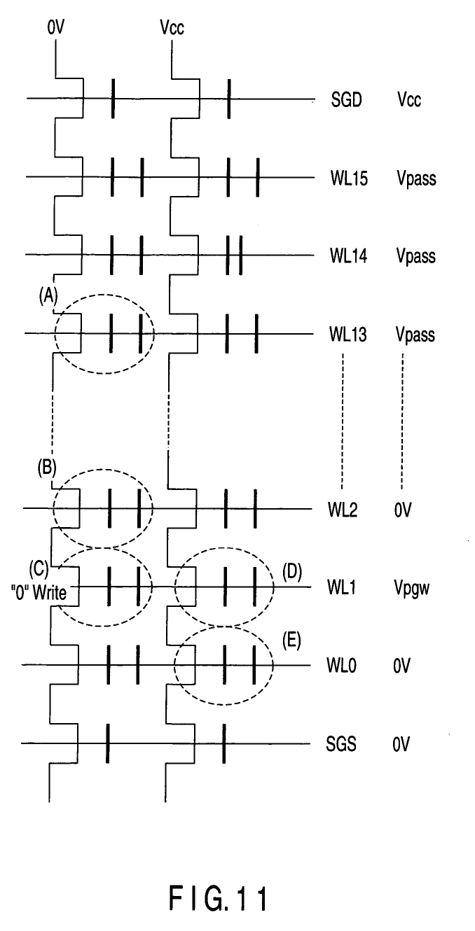

FIGS. 10A and 10B show diagrams showing sectional structures of the memory transistors and band diagrams, FIG. 10A is a diagram which relates to a conventional memory transistor, and FIG. 10B is a diagram which relates to the memory transistor of the first embodiment. Unlike the conventional memory transistor shown in FIG. 10A, in the memory transistor of the first embodiment shown in FIG. 10B, the only edge portion of the floating gate 4 is formed into n+poly. In the transistor formed in this manner, as shown in FIG. 10B, a voltage applied to the gate edge portion can be lowered (Vox1>Vox2) as compared with FIG. 10A. Therefore, in a cell array structure shown in FIG. 11, in a cell (C) into which “0” has been written, any electron does not come off by the voltage applied to the gate edge portion during the writing of the adjacent cell, and erroneous erase “0”→“1” does not occur. The device does not have any problem even in the other cells (A), (B), (D), and (E).

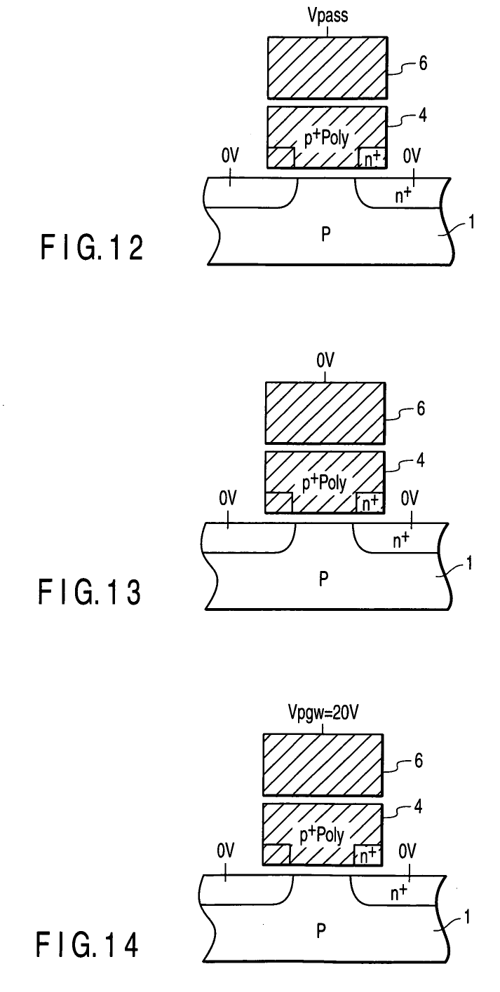

FIGS. 12 to 16 are diagrams showing a state of the memory transistor in the first embodiment. FIG. 12 shows the cell (A) of FIG. 11 which is not subjected to the write (remains to be “1”). The voltage applied to the oxide film is larger in n+poly of the gate edge portion than in p+poly, but there is little influence because Vpass<Vpgw. It is to be noted that Vpgw is a voltage applied to the word line of the “0”-written cell, and Vpass is a voltage applied to the word line of the cell held in a state “1”. FIG. 13 shows the cell (B) of FIG. 11 (remains to be “1”), that is, the cell adjacent to the “0”-written cell (C), and there is not any relation because all of the gate, the source, and the drain indicate 0 V.

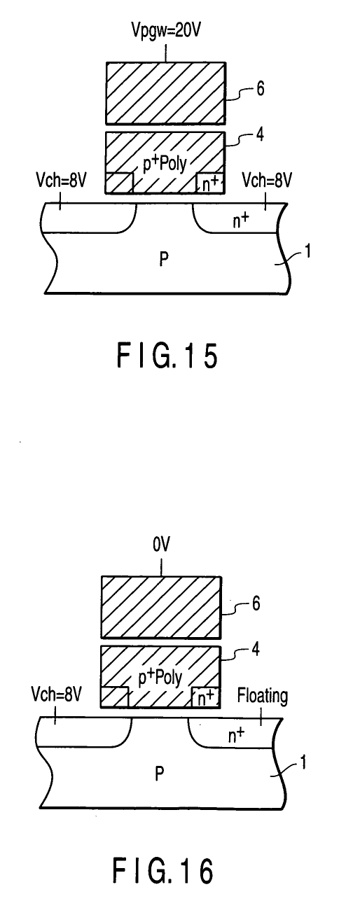

FIG. 14 shows the “0”-written cell (C) of FIG. 11. Since the impurities of a channel portion do not change, there is not any influence on the write. A part of the electrode is formed into n+ to thereby reduce a channel area. FIG. 15 shows the cell (D) of FIG. 11 (remains to be “1”) which is not written. Since the impurities of the channel portion do not change, “1”→“0” does not result. FIG. 16 shows the “0”-written cell (E) of FIG. 11. The gate edge portion can be formed into n+ to thereby reduce the voltage applied to the edge portion, and erroneous erase (“0”→“1”) does not easily occur.

In the first embodiment, the amorphous silicon film to which boron has been added is formed as the floating gate 4, and phosphor is ion-implanted into the gate edge portion. The impurities are not limited to boron and phosphor. When the gate is formed into p+poly, and the edge portion is formed into n+poly, there is not any problem even in a case where another impurity is used. Furthermore, even if n+poly and p+poly are reversed to reverse a bias of the applied voltage, there is not any problem.

In a second embodiment, in steps of manufacturing a cell array of a NAND type flash memory, first there are performed the same steps as those described in the first embodiment with reference to FIGS. 2 to 5. Next, the following steps are performed.

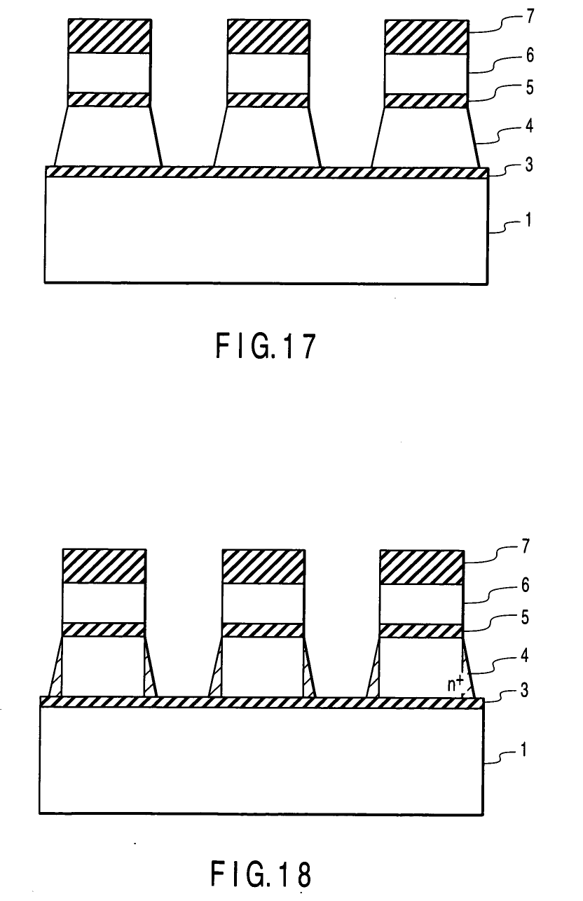

FIGS. 17 to 19 are sectional views cut along the line A-A′ of FIG. 1A. There will be described hereinafter the steps of manufacturing the cell array of the NAND type flash memory with reference to FIGS. 17 to 19.

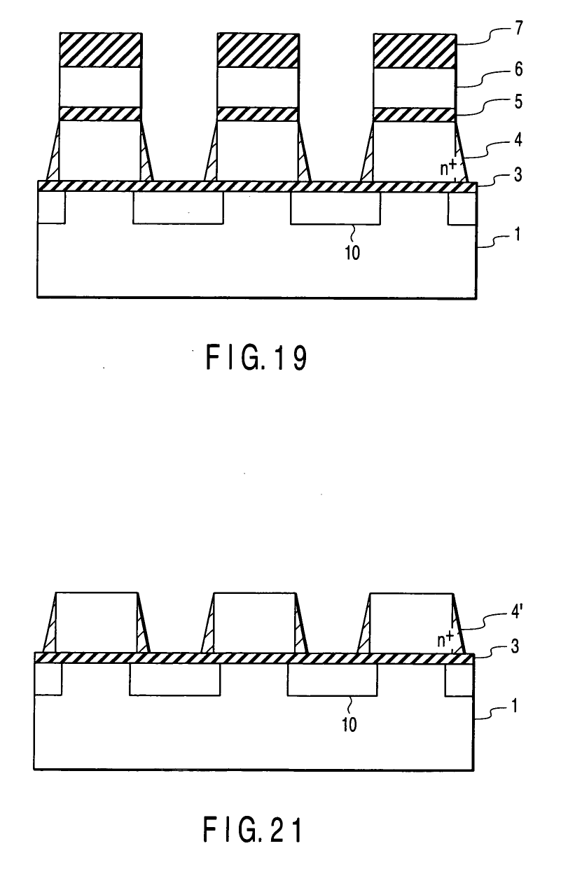

After the photo resist 8 shown in FIG. 5 is removed, as shown in FIG. 17, a control gate 6 and a second gate insulating film 5 are successively etched in a vertical direction by use of a silicon nitride film 7 as a mask. Thereafter, RIE is performed while a gas pressure is raised, and a floating gate 4 is tapered. That is, the floating gate 4 has a tapered shape in which a side portion of the floating gate 4 is enlarged toward the surface of the silicon substrate 1. Furthermore, as shown in FIG. 18, phosphor is ion-implanted in the edge portion of the floating gate 4 to form the floating gate 4 in which a side wall of p+poly is formed into n+. Moreover, as shown in FIG. 19, to form a source and a drain, ions are implanted in a silicon substrate 1, the substrate is activated by thermal annealing to form a diffusion layer 10, and a memory transistor is formed.

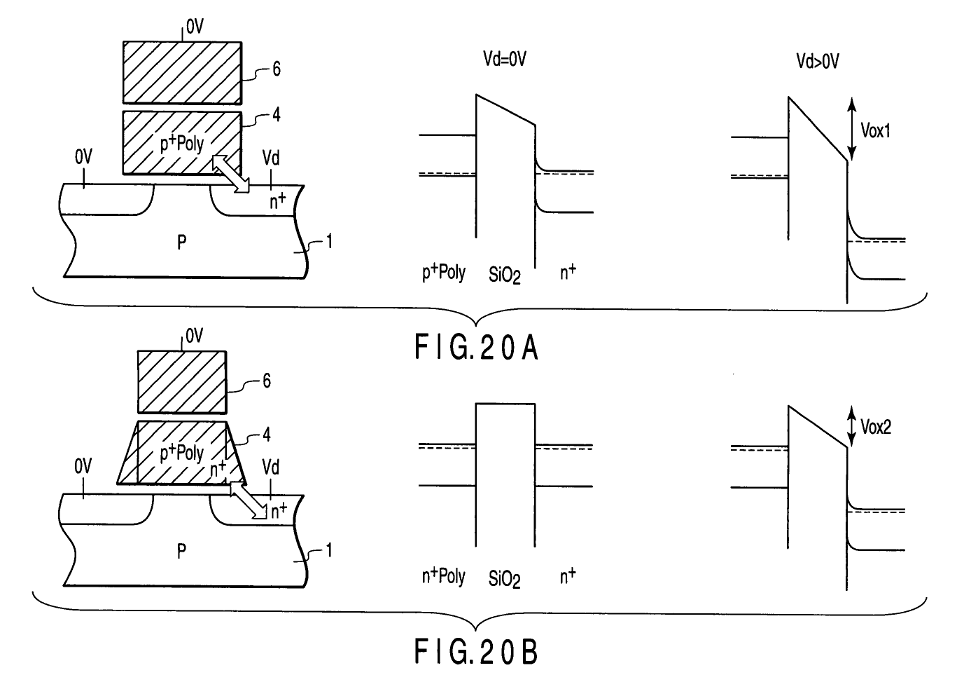

FIGS. 20A and 20B show diagrams showing sectional structures of the memory transistors and band diagrams, FIG. 20A is a diagram which relates to a conventional memory transistor, and FIG. 20B is a diagram which relates to the memory transistor of the second embodiment. Unlike the conventional memory transistor shown in FIG. 20A, in the memory transistor of the second embodiment shown in FIG. 20B, the only edge portion of the floating gate 4 is formed into n+poly. In the transistor formed in this manner, as shown in FIG. 20B, a voltage applied to the gate edge portion can be lowered (Vox1>Vox2) as compared with FIG. 20A. As a result, in a cell array structure shown in FIG. 11, erroneous erase “0”→“1” does not occur in a cell (C) into which “0” has been written during the writing of the adjacent cell in the same manner as in the first embodiment. The device does not have any problem even in the other cells (A), (B), (D), and (E).

In the second embodiment, the amorphous silicon film to which boron has been added is formed as the floating gate 4, and phosphor is ion-implanted into the gate edge portion. However, the impurities are not limited to boron and phosphor. When the gate is formed into p+poly, and the edge portion is formed into n+poly, there is not any problem even in a case where another impurity is used. Furthermore, even if n+poly and p+poly are reversed to reverse a bias of the applied voltage, there is not any problem.

FIG. 21 shows a diagram showing a sectional structure of a MOSFET that is a modification of the second embodiment. The second embodiment can also be applied to a MOSFET having one gate electrode. In FIG. 21, the same part as that of FIG. 19 is denoted with the same reference numerals. In FIG. 21, a gate electrode 4′ is tapered, and phosphor is ion-implanted in the edge portion of the gate electrode 4′ to form the gate electrode 4′ in which a side wall of p+poly is formed into n+. That is, the floating gate 4 has a tapered shape in which a side portion of the floating gate 4 is enlarged toward the surface of the silicon substrate 1. The MOSFET structured as described above can also achieve the same advantages as in the case of the NAND type flash memory described above.

In a third embodiment, in steps of manufacturing a cell array of a NAND type flash memory, first there are performed the same steps as those described in the first embodiment with reference to FIGS. 2 to 5. Next, the following steps are performed.

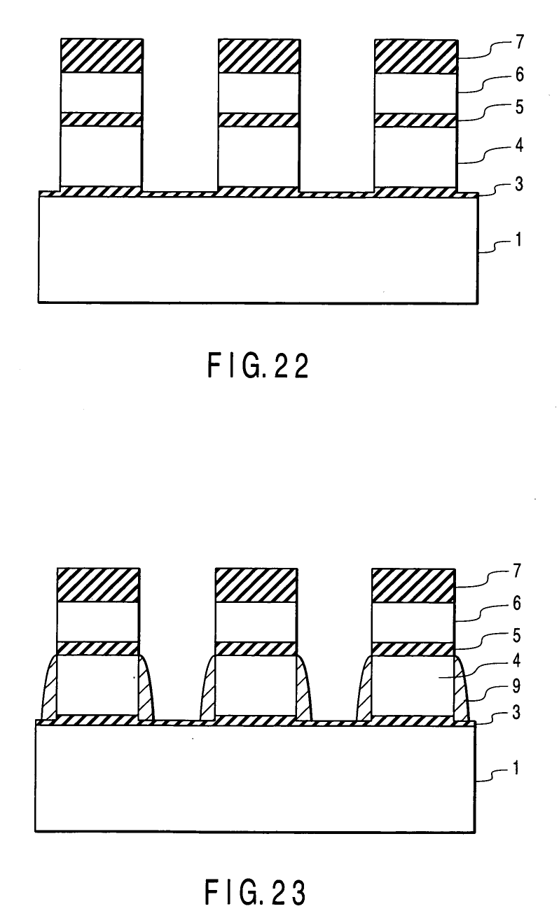

FIGS. 22 to 25 are sectional views cut along the line A-A′ of FIG. 1A. There will be described hereinafter the steps of manufacturing the cell array of the NAND type flash memory with reference to FIGS. 22 to 25.

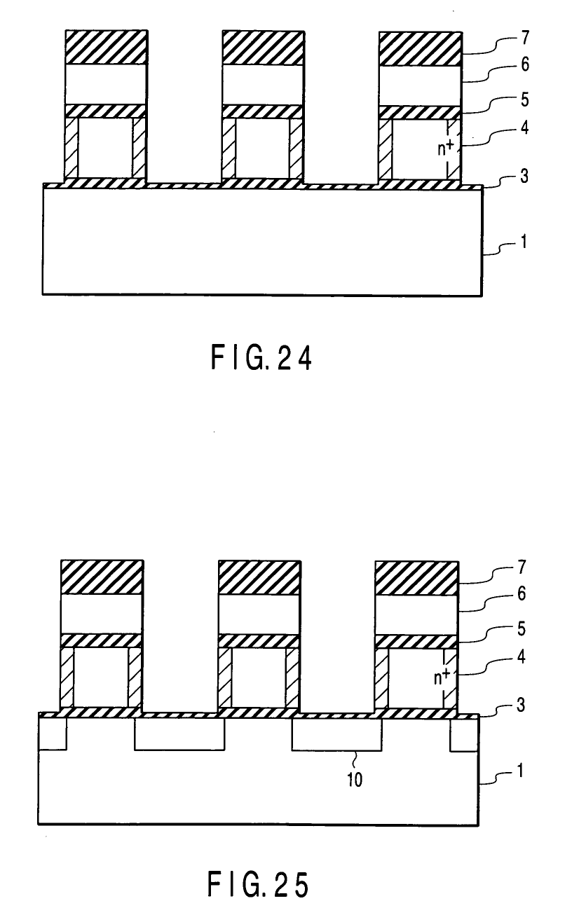

After the photo resist 8 shown in FIG. 5 is removed, as shown in FIG. 22, a control gate 6, a second gate insulating film 5, and a floating gate 4 are successively etched in a vertical direction by use of a silicon nitride film 7 as a mask. Furthermore, as shown in FIG. 23, a phosphor silicate glass (PSG) film is formed around the whole gate. Thereafter, the film is etched back, and a PSG film 9 is left on an only side portion of the floating gate 4. Next, as shown in FIG. 24, the film is annealed to diffuse phosphor from the PSG film 9 to the floating gate 4, and the edge portion of the floating gate 4 is formed into n+poly. Thereafter, PSG is peeled by performing wet etching. Furthermore, as shown in FIG. 25, to form a source and a drain, ions are implanted in a silicon substrate 1, the substrate is activated by thermal annealing to form a diffusion layer 10, and a memory transistor is formed.

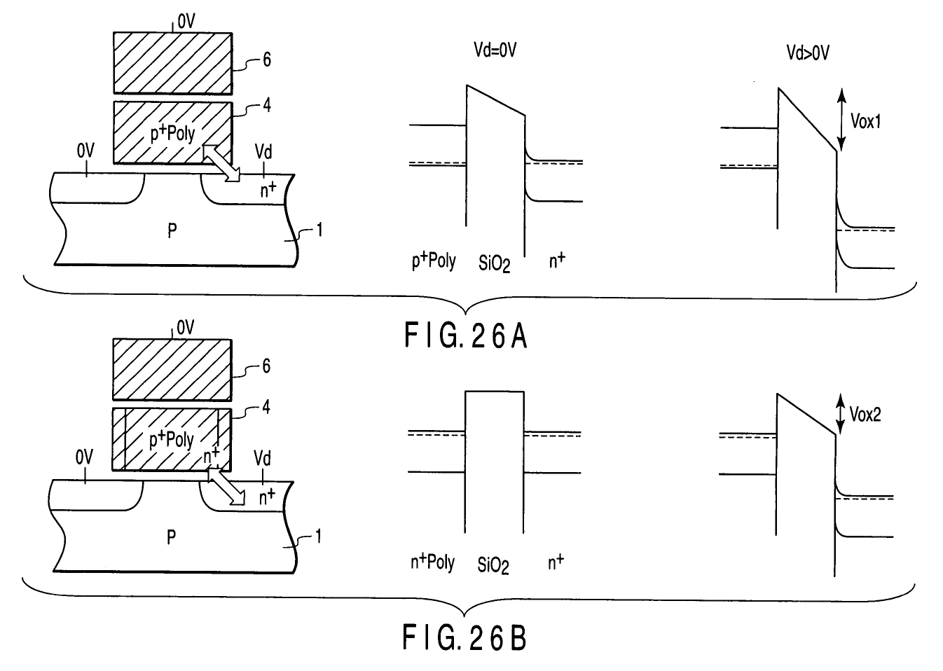

FIGS. 26A and 26B show diagrams showing sectional structures of the memory transistors and band diagrams, FIG. 26A is a diagram which relates to a conventional memory transistor, and FIG. 26B is a diagram which relates to the memory transistor of the third embodiment. Unlike the conventional memory transistor shown in FIG. 26A, in the memory transistor of the third embodiment shown in FIG. 26B, the only edge portion of the floating gate 4 is formed into n+poly. In the transistor formed in this manner, as shown in FIG. 26B, a voltage applied to the gate edge portion can be lowered (Vox1>Vox2) as compared with FIG. 26A. As a result, in a cell array structure shown in FIG. 11, erroneous erase “0”→“1” does not occur in a cell (C) into which “0” has been written during the writing of the adjacent cell in the same manner as in the first embodiment. The device does not have any problem even in the other cells (A), (B), (D), and (E).

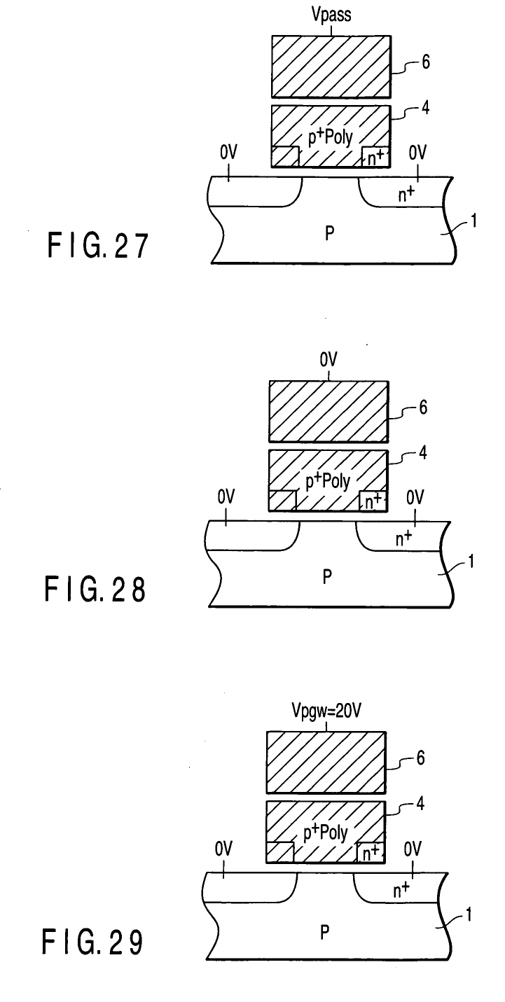

FIGS. 27 to 31 are diagrams showing a state of the memory transistor in the third embodiment. FIG. 27 shows the cell (A) of FIG. 11 which is not subjected to the write (remains to be “1”). The voltage applied to the oxide film is larger in n+poly of the gate edge portion than in p+poly, but there is little influence because Vpass<Vpgw. FIG. 28 shows the cell (B) of FIG. 11 (remains to be “1”), that is, the cell adjacent to the “0”-written cell (C), and there is not any relation because all of the gate, the source, and the drain indicate 0 V.

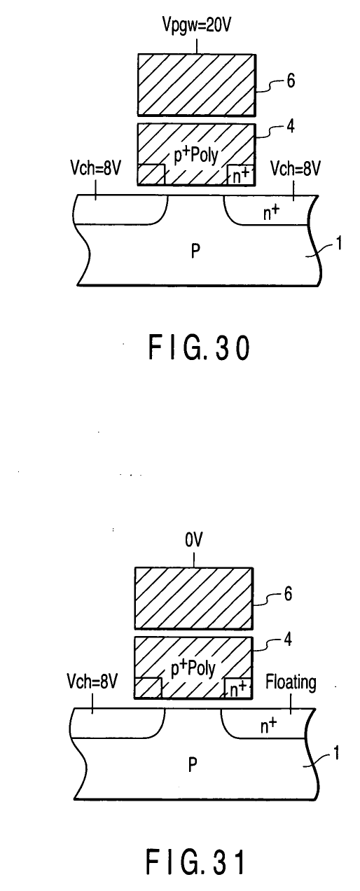

FIG. 29 shows the “0”-written cell (C) of FIG. 11. The voltage Vpgw applied to p+poly can be reduced as compared with n+poly. A part of the electrode is formed into n+ to thereby reduce a channel area. FIG. 30 shows the cell (D) of FIG. 11 (remains to be “1”) which is not written. The voltage applied to the oxide film is larger in n+poly of the gate edge portion than in p+poly. However, since the state is formed into p+poly, Vpgw is smaller than the voltage of the cell (C). Therefore, the voltage applied to the gate edge portion can be reduced. FIG. 31 shows the “0”-written cell (E) of FIG. 11. The gate edge portion can be formed into n+ to thereby reduce the voltage applied to the edge portion, and erroneous erase (“0”→“1”) does not easily occur.

In the third embodiment, the amorphous silicon film to which boron has been added is formed as the floating gate 4, and phosphor is diffused from the PSG film to the gate edge portion, but the impurities are not limited to boron and phosphor. When the gate is formed into p+poly, and the edge portion is formed into n+poly, there is not any problem even in a case where another impurity is used. Furthermore, even if n+poly and p+poly are reversed to reverse a bias of the applied voltage, there is not any problem.

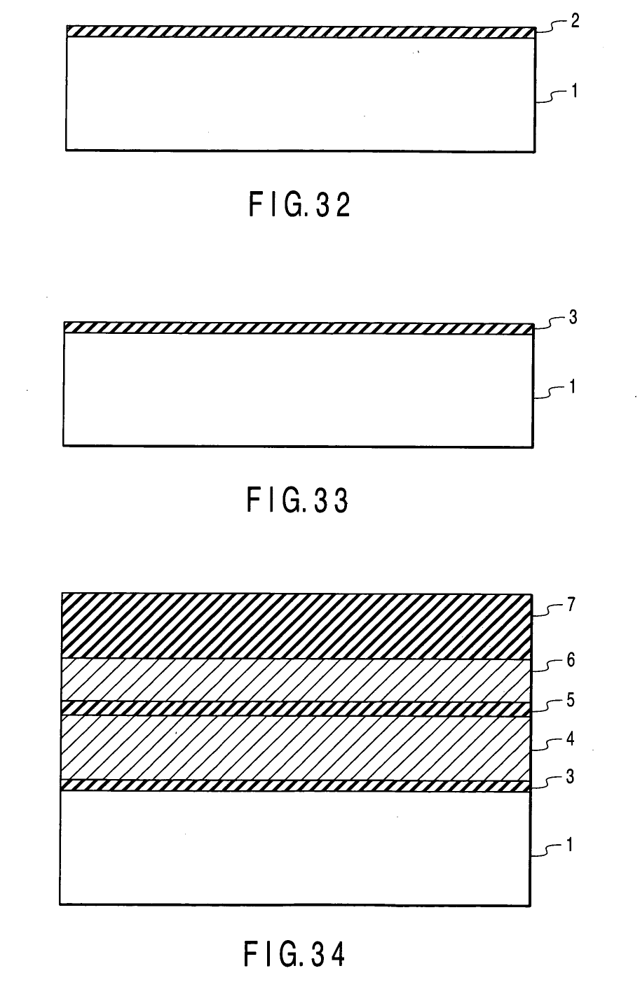

FIGS. 32 to 40 are sectional views cut along the line A-A′ of FIG. 1A. There will be described hereinafter steps of manufacturing a cell array of a NAND type flash memory with reference to FIGS. 32 to 40.

First, as shown in FIG. 32, a silicon oxide film 2 is formed on a silicon substrate 1 by use of a thermal oxidation method. This silicon oxide film 2 is nitrided by use of an NH₃ gas, and oxidized to thereby form an oxynitride film 3 as shown in FIG. 33. This oxynitride film 3 works as a first gate insulating film, and is generally referred to as a tunnel oxide film.

Furthermore, as shown in FIG. 34, there is formed a silicon film 4 to which boron (B) has been added as impurities on the oxynitride film 3 by use of a CVD method. This silicon film 4 forms a first gate electrode. In general, this silicon film 4 is referred to as a floating gate. Subsequently, a second gate insulating film 5 having a film thickness of 120 nm is formed on this floating gate 4 by use of an LPCVD method. Next, there is formed a silicon film 6 to which boron (B) has been added as impurities on the second gate insulating film 5 by use of the LPCVD method. This silicon film 6 forms a second gate electrode, and is generally referred to as a control gate. Subsequently, a silicon nitride film 7 is formed on this control gate 6 by the LPCVD method.

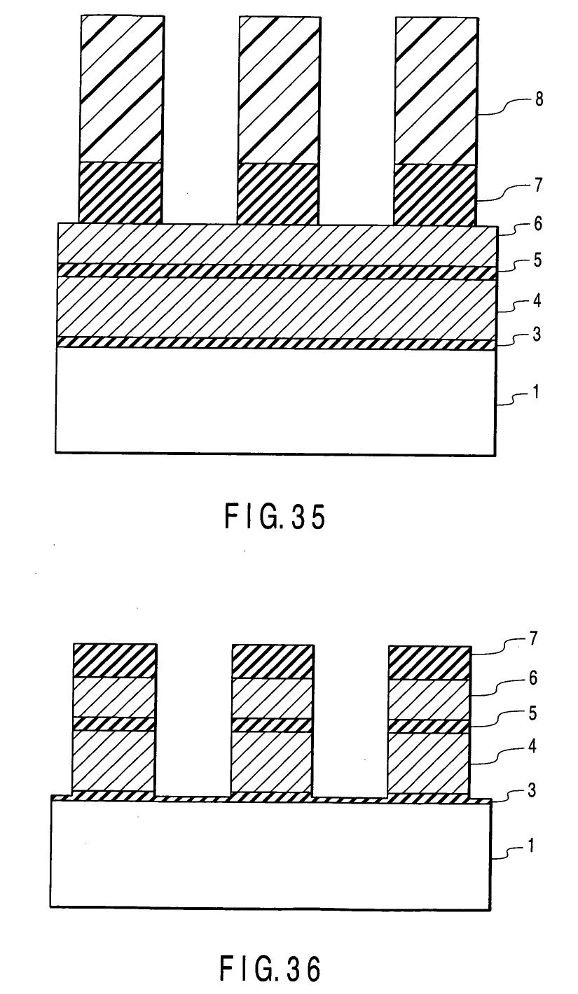

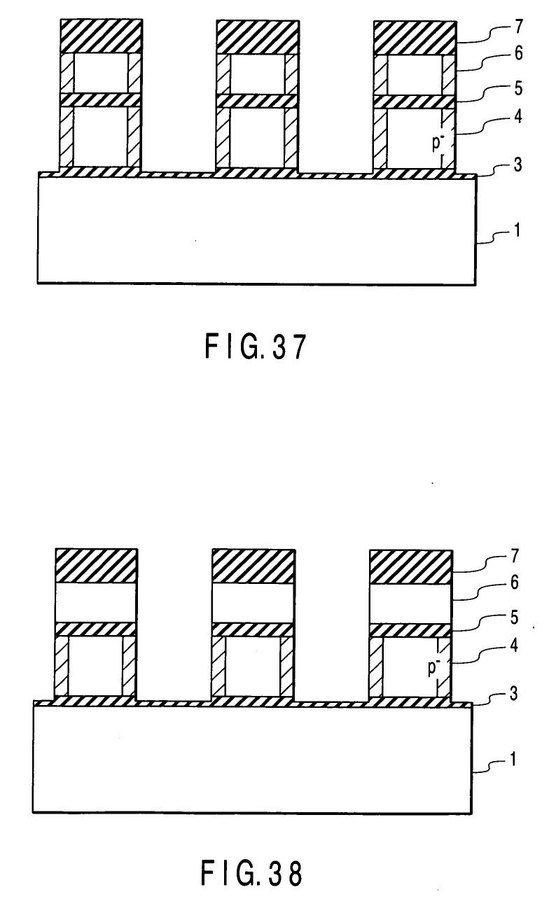

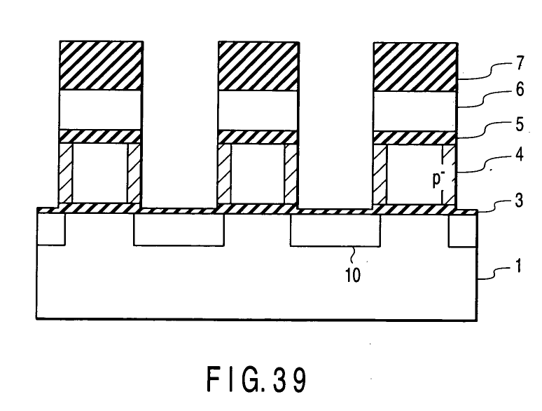

Furthermore, as shown in FIG. 35, the silicon nitride film 7 is coated with a photo resist 8. A desired pattern is worked using a lithography method, and subsequently the photo resist 8 is removed. As shown in FIG. 36, the control gate 6, the second gate insulating film 5, and the floating gate 4 are successively etched in a vertical direction by use of the nitride film 7 as a mask. Furthermore, as shown in FIG. 37, phosphor (P) is ion-implanted obliquely from above into an edge portion of the floating gate 4. Accordingly, p+poly, for example, a side wall of a p-type polysilicon having an impurity concentration of about 2×10²⁰ atom/cm³ forms the floating gate 4 which is a p-type impurity area (p−) having an impurity concentration of, for example, about 1×10¹⁴ atom/cm³. Next, as shown in FIG. 38, boron is ion-implanted with an angle obliquely from above, and the control gate 6 is formed into p+poly. Furthermore, as shown in FIG. 39, to form a source and a drain, ions are implanted in the silicon substrate 1, the substrate is activated by thermal annealing to form a diffusion layer 10, and a memory transistor is formed.

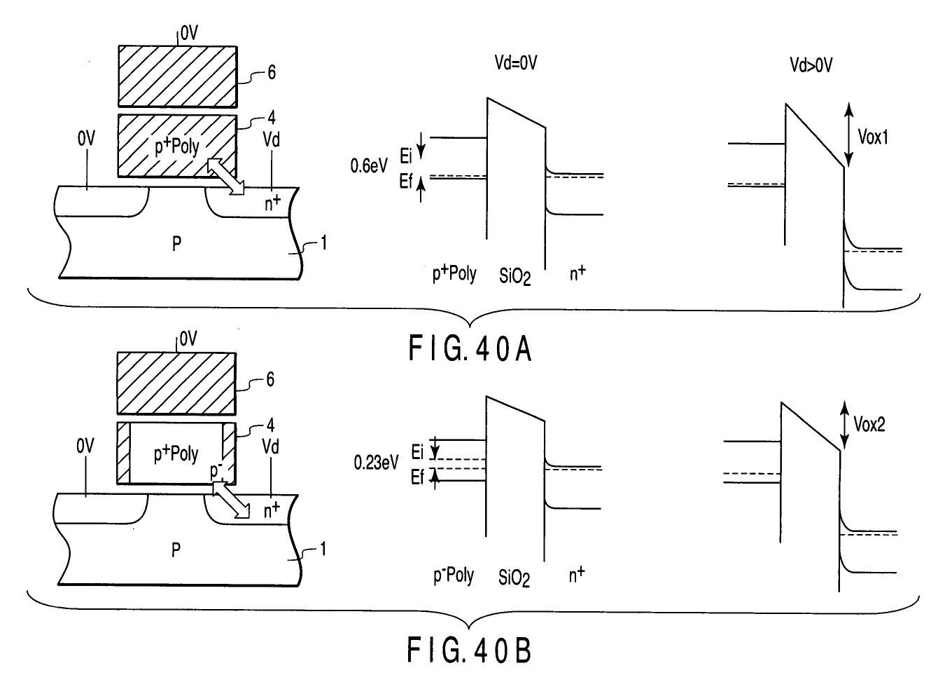

FIGS. 40A and 40B show diagrams showing sectional structures of the memory transistors and band diagrams, FIG. 40A is a diagram which relates to a conventional memory transistor, and FIG. 40B is a diagram which relates to the memory transistor of the fourth embodiment. Unlike the conventional memory transistor shown in FIG. 40A, in the memory transistor of the fourth embodiment shown in FIG. 40B, the only edge portion of the floating gate 4 is formed into p−poly. In the transistor formed in this manner, as shown in FIG. 40B, a voltage applied to the gate edge portion can be lowered (Vox1>Vox2) as compared with FIG. 40A.

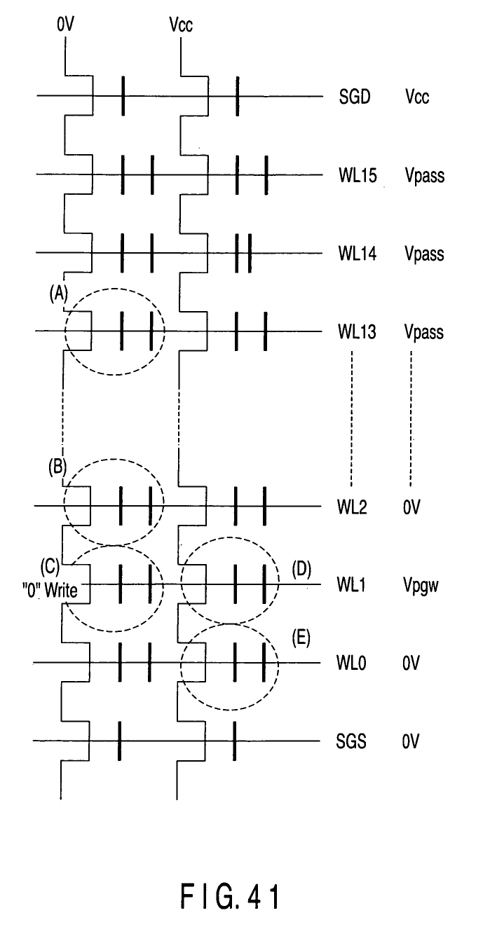

For example, in a case where the floating gate 4 has an impurity concentration of 2×10²⁰ atom/cm³, and the edge portion of the floating gate 4 has an impurity concentration of 1×10¹⁴ atom/cm³, the Fermi levels are 0.6 eV and 0.23 eV from Ef−Ei=kT×1n (Na/Ni) as viewed from an intrinsic semiconductor. Therefore, the edge portion of the floating gate 4 can be formed into p− to lower a voltage 0.6−0.23=0.37 V. Therefore, as shown in FIG. 41, in a cell (E) into which “0” has be written, any electron does not come off by a voltage applied to the gate edge portion during the writing of an adjacent cell, and erroneous erase “0”→“1” does not occur. The device does not have any problem in the other cells (A) to (D).

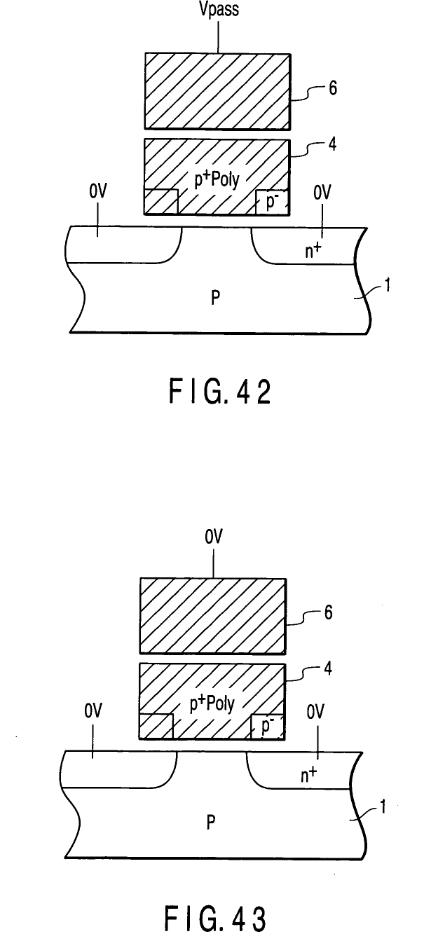

FIGS. 42 to 46 are diagrams showing a state of the memory transistor in the fourth embodiment. FIG. 42 shows the cell (A) of FIG. 41 which is not subjected to the write (remains to be “1”). The voltage applied to the oxide film is larger in p−poly of the gate edge portion than in p+poly, but there is little influence because Vpass<Vpgw. FIG. 43 shows the cell (B) of FIG. 41 (remains to be “1”), that is, the cell adjacent to the “0”-written cell (C), and there is not any relation because all of the gate, the source, and the drain indicate 0 V.

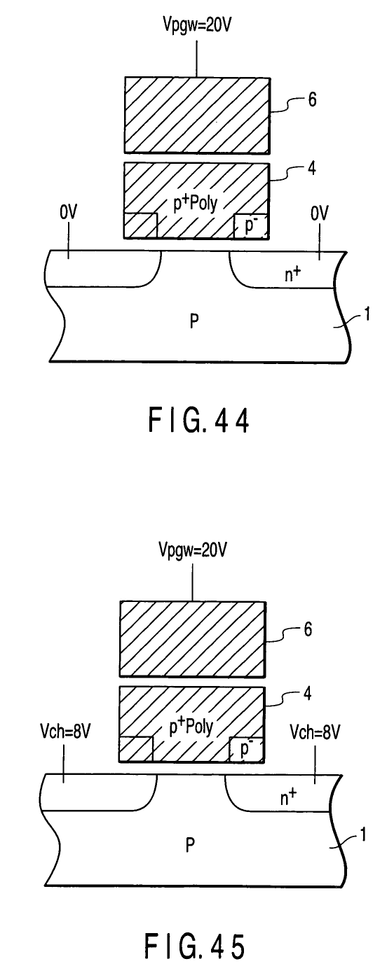

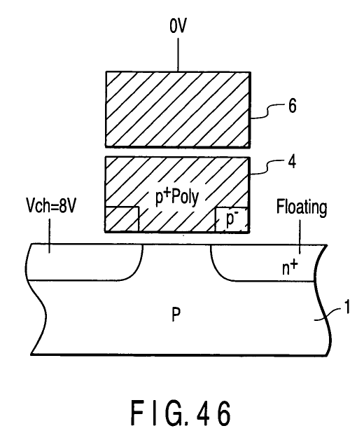

FIG. 44 shows the “0”-written cell (C) of FIG. 41. Since the impurities of a channel portion do not change, there is not any influence on the write. A part of the electrode is formed into p− to thereby reduce a channel area. FIG. 45 shows the cell (D) of FIG. 41 (remains to be “1”) which is not written. Since the impurities of the channel portion do not change, “1”→“0” does not result. FIG. 46 shows the “0”-written cell (E) of FIG. 41. The gate edge portion can be formed into p− to thereby reduce the voltage applied to the edge portion, and erroneous erase (“0”→“1”) does not easily occur.

In the fourth embodiment, the amorphous silicon film to which boron has been added is formed as the floating gate 4, and phosphor is ion-implanted into the gate edge portion. However, the impurities are not limited to boron and phosphor. When the gate is formed into p+poly, and the edge portion is formed into p−poly, there is not any problem even in a case where another impurity is used. Furthermore, even if p+poly and p−poly are changed to n+poly and n−poly to reverse a bias of the applied voltage, there is not any problem.

As described above, according to the embodiments of the present invention, the voltage applied to the gate edge portion can be lowered without changing the voltage applied to the channel portion. The voltage applied to the oxide film between the diffusion layer and the gate electrode is reduced as compared with the voltage applied to the oxide film of another portion. Therefore, erroneous erase (“0”→“1”) does not occur in the “0”-written cell during the writing of another cell.

That is, the impurities different from those added to the other portion of the gate electrode are added to the edge portion of the gate electrode. Accordingly, it is possible to lower the voltage applied to the gate edge portion without changing the voltage of the channel portion, and it is possible to prevent the electrons from coming off the floating gate.

According to the present embodiments, it is possible to provide a semiconductor device in which erroneous erase does not occur in the written cell during the writing of the other cell, and a method of manufacturing the device.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

What is claimed is:

1. A semiconductor device comprising:
a semiconductor substrate;
a gate insulating film formed on the semiconductor substrate;
a gate electrode formed on the gate insulating film; and
a diffusion layer formed in the semiconductor substrate,
a predetermined portion of the gate electrode in the vicinity of the diffusion layer being provided with an impurity area whose conductive type is different from that of another portion of the gate electrode or an impurity area whose conductive type is the same as that of the other portion and whose concentration is lower than that of the other portion.

2. The semiconductor device according to claim 1, wherein the gate electrode is a floating gate.

3. The semiconductor device according to claim 1, wherein the predetermined portion is an edge portion;

4. The semiconductor device according to claim 1, wherein the gate electrode is p+poly, and the impurity area is n+poly.

5. The semiconductor device according to claim 1, wherein the gate electrode is n+poly, and the impurity area is p+poly.

6. The semiconductor device according to claim 1, wherein a voltage applied between the predetermined portion of the gate electrode and the diffusion layer is smaller than that applied between the another portion of the gate electrode and the semiconductors substrate.

7. The semiconductor device according to claim 1, wherein the gate electrode has a tapered shape in which a side portion thereof is enlarged toward the surface of the semiconductor substrate.

8. A semiconductor device comprising:
a semiconductor substrate;
a first gate insulating film formed on the semiconductor substrate;
a first gate electrode formed on the first gate insulating film;
a second gate insulating film formed on the first gate electrode;
a second gate electrode formed on the second gate insulating film; and
a diffusion layer formed in the semiconductor substrate,
a predetermined portion of the first gate electrode in the vicinity of the diffusion layer being provided with an impurity area whose conductive type is different from that of another portion of the first gate electrode or an impurity area whose conductive type is the same as that of the other portion and whose concentration is lower than that of the other portion.

9. The semiconductor device according to claim 8, wherein the first gate electrode is a floating gate, and the second gate electrode is a control gate.

10. The semiconductor device according to claim 8, wherein the predetermined portion is an edge portion;

11. The semiconductor device according to claim 8, wherein the first gate electrode is p+poly, and the impurity area is n+poly.

12. The semiconductor device according to claim 8, wherein the first gate electrode is n+poly, and the impurity area is p+poly.

13. The semiconductor device according to claim 8, wherein a voltage applied between the predetermined portion of the first gate electrode and the diffusion layer is smaller than that applied between the another portion of the first gate electrode and the semiconductors substrate.

14. The semiconductor device according to claim 8, wherein the first gate electrode has a tapered shape in which a side portion thereof is enlarged toward the surface of the semiconductor substrate.

15. A method of manufacturing a semiconductor device, comprising:
forming a gate insulating film on a semiconductor substrate;
forming a gate electrode on the gate insulating film;
implanting impurities in a predetermined portion of the gate electrode; and
forming a diffusion layer in the semiconductor substrate,
a predetermined portion of the gate electrode in the vicinity of the diffusion layer being provided with an impurity area whose conductive type is different from that of another portion of the gate electrode or an impurity area whose conductive type is the same as that of the other portion and whose concentration is lower than that of the other portion.

16. The method of manufacturing the semiconductor device according to claim 15, wherein the impurities are implanted obliquely from above the predetermined portion.

17. The semiconductor device according to claim 15, wherein the gate electrode has a tapered shape in which a side portion thereof is enlarged toward the surface of the semiconductor substrate.

18. A method of manufacturing a semiconductor device, comprising:
forming a first gate insulating film on a semiconductor substrate;
forming a first gate electrode on the first gate insulating film;
forming a second gate insulating film on the first gate electrode;
forming a second gate electrode on the second gate insulating film;
implanting impurities in a predetermined portion of the first gate electrode; and
forming a diffusion layer in the semiconductor substrate,
a predetermined portion of the first gate electrode in the vicinity of the diffusion layer being provided with an impurity area whose conductive type is different from that of another portion of the first gate electrode or an impurity area whose conductive type is the same as that of the other portion and whose concentration is lower than that of the other portion.

19. The method of manufacturing the semiconductor device according to claim 18, wherein the impurities are implanted obliquely from above the predetermined portion.

20. The semiconductor device according to claim 18, wherein the first gate electrode has a tapered shape in which a side portion thereof is enlarged toward the surface of the semiconductor substrate.
